(19) United States
(12) Patent Application Publication
(10) Pub. No.: US 2011/0204027 A1
(43) Pub. Date: Aug. 25, 2011

(54) SLURRY MANUFACTURING METHOD, SLURRY AND POLISHING METHOD AND APPARATUS USING SLURRY

(75) Inventor: Tsuyoshi MORIYA, Tokyo (JP)

(73) Assignee: TOKYO ELECTRON LIMITED, Tokyo (JP)

(21) Appl. No.: 13/031,653

(22) Filed: Feb. 22, 2011

(30) Foreign Application Priority Data
Feb. 23, 2010 (JP) 2010-037397

(51) Int. Cl. C03C 15/02; C09K 13/00; B05D 7/00; H01L 21/306

(52) U.S. Cl. 216/53; 252/79.1; 427/212; 156/345.12; 205/662

(57) ABSTRACT

Abrasive particles having a particle diameter of not more than 100 nm are manufactured from raw material. The manufactured abrasive particles are separately dispersed, and are coated with a polymer. Coated abrasive particles having a particle diameter of not more than 100 nm are selected and are mixed with a liquid component of a slurry to manufacture the slurry. A pH adjuster and a viscosity agent are added to the slurry. A glass substrate is polished using the manufactured slurry. Since the abrasive particles having a particle diameter of more than 100 nm or an agglomerate of the cohering abrasive particles does not contact the glass and does not cause big scratches on the glass, the generation of the scratches of 70 nm or more on the glass during polishing are suppressed.

### CROSS-REFERENCE TO RELATED APPLICATIONS

This application is based upon and claims the benefit of priority from Japanese Patent Application No. 2010-037397, filed on Feb. 23, 2010, the entire contents of which are incorporated herein by reference.

### TECHNICAL FIELD

The present disclosure relates to a method of manufacturing a slurry for use in polishing glass, and to such a slurry. The present disclosure further relates to a polishing method and apparatus using such a slurry.

### BACKGROUND

Circuit patterns on electronic components such as a semiconductor element are made by using an exposure technology, for example, by reductively projecting a negative circuit pattern formed on a photo mask to a silicon wafer. To promote miniaturization of electronic components, the wavelength of a light for use in an exposure technology becomes shorter. Recently, an EUV exposure technology using an EUV (Extreme Ultraviolet) light as an exposure light has been developed. A photo mask for the EUV exposure is structured such that a multi-layered film including metal and semiconductor for reflecting an EUV light is provided on a mask blank (substrate material) and a negative circuit pattern including a light absorber is formed on the multi-layered film. A mask blank is manufactured by chemical mechanical polishing (CMP) of a glass substrate. Defects on a surface of a mask blank cause defects in a multi-layered film and lead to deterioration in precision of a negative circuit pattern. Accordingly, when manufacturing the mask blank by means of the CMP, there is a need to prevent the defects, if possible. The CMP is performed by using a polishing liquid (referred to as a slurry in the art) that contains abrasive particles for polishing a glass substrate. By way of example of such a polishing liquid, Japanese Laid-Open Patent Publication No. 2004-98278 discloses a slurry for use in manufacturing a mask blank.

### SUMMARY

When a mask blank has scratches of 70 nm or more on its surface, a photo mask for the EUV exposure with an inferior negative circuit pattern can be manufactured. Accordingly, when manufacturing mask blanks, there is a need to make scratches generated on a glass substrate during CMP less than at least 70 nm. One factor associated with such scratches on the glass substrate is that the abrasive particles contained in the slurry are pressed against the surface of the glass substrate during polishing and such force from being pressed is concentrated on contact points between the abrasive particles and the glass substrate. As an approach of suppressing the generation of the scratches, it may be considered to reduce the particle diameters of the abrasive particles. However, this approach is problematic in that smaller abrasive particles are prone to cohere in the slurry and the cohering abrasive particles, in turn, cause scratches on the glass substrate.

Thus, in light of the foregoing, it is an object of some embodiments of the present disclosure to provide a slurry that will make it difficult to cause scratches on glass and a method of manufacturing such a slurry. It is another object of some embodiments of the present disclosure to provide a polishing method and a polishing apparatus which suppress the generation of the scratches by using such a slurry.

According to one aspect of the present disclosure, there are provided embodiments of a method of manufacturing a slurry. In one embodiment, the slurry contains abrasive particles for polishing a glass, and a liquid component. The abrasive particles having a particle diameter of not more than 100 nm is manufactured. The manufactured abrasive particles are dispersed. The abrasive particles are mixed with the liquid component as the abrasive particles are dispersed.

In one embodiment, the dispersed abrasive particles are coated with a polymer softer than the abrasive particle.

In another embodiment, the abrasive particle includes: a substance for mechanically polishing the glass as a main component; and a substance for chemically reacting with the glass as a minor component.

In yet another embodiment, the abrasive particle having a particle diameter of not more than 100 nm are selected prior to mixing the abrasive particles with the liquid component.

In one embodiment, a pH adjuster is added to maintain a pH of 7 or more.

In yet another embodiment, a viscosity agent is added.

According to a further aspect of the present disclosure, there are provided embodiments of a slurry. In one embodiment, the slurry comprises: abrasive particles for polishing a glass; and a liquid component. The slurry does not contain abrasive particles having a particle diameter of more than 100 nm. The abrasive particles having a particle diameter of not more than 100 nm are dispersed in the liquid component.

In one embodiment, the abrasive particle includes a nucleus and a polymer softer than the nucleus. The nucleus is coated with the polymer.

In another embodiment, the abrasive particle includes: a substance for mechanically polishing the glass as a main component; and a substance for chemically reacting with the glass as a minor component.

In one embodiment, a pH of the slurry is maintained as 7 or more.

In another embodiment, the slurry further comprises a viscosity agent.

According to another aspect of the present disclosure, there are provided embodiments of a method of chemical mechanical polishing a glass using the slurry according to the embodiments.

In one embodiment, a temperature of the slurry is controlled so as to be higher than an atmospheric temperature around the slurry.

In another embodiment, a voltage is applied to the slurry and ions having the same polarity as the voltage are supplied around the slurry.

According to still another aspect of the present disclosure, there are provided embodiments of a polishing apparatus. In one embodiment, the polishing apparatus includes: a device for feeding the slurry according to the embodiments; a device for polishing glass using the fed slurry; and a device for controlling a temperature of the slurry so as to be higher than an atmospheric temperature around the slurry. In another embodiment, the polishing apparatus includes: a device for feeding the slurry according to the embodiments; a device for polishing glass by using the fed slurry; a device for applying a voltage to the slurry; and a device for supplying ions having the same polarity as the voltage around the slurry.

In some embodiments, a slurry, wherein the abrasive particles having a particle diameter of not more than 100 nm are dispersed in the liquid component, are manufactured as a slurry for use in polishing glass.

In one embodiment, the abrasive particles contained in the slurry are coated with a soft polymer.

In another embodiment, the abrasive particle contained in the slurry includes: silica for mechanically polishing the glass as a main component; and alumina for chemically reacting with the glass as a minor component.

In yet another embodiment, as to the abrasive particles to be contained in the slurry, the abrasive particles having a particle diameter of not more than 100 nm are selected such that the slurry does not contain the abrasive particles having a particle diameter of more than 100 nm.

In one embodiment, the pH adjuster is added to the slurry in order to keep the slurry alkaline.

In another embodiment, the viscosity agent is added to the slurry in order to control the viscosity of the slurry.

In one embodiment, a temperature of the slurry is controlled so as to be higher than an atmospheric temperature around the slurry when polishing the glass by using the slurry.

In one embodiment, a voltage is applied to the slurry and ions having the same polarity as the voltage are irradiated around the slurry, when polishing the glass by using the slurry.

### BRIEF DESCRIPTION OF THE DRAWINGS

FIG. 1 is a conceptual diagram schematically showing example processes of a slurry-manufacturing method.

FIG. 2 is a schematic diagram showing an example of an apparatus for manufacturing abrasive particles by a gas phase synthesis method.

FIG. 3 is a sectional view schematically showing an example of an apparatus for manufacturing abrasive particles by an aerosol heating method.

FIG. 4 is a schematic sectional view showing an example of a bead mill.

FIG. 5 is a characteristic diagram showing a particle diameter distribution of the abrasive particles before and after a process using the bead mill.

FIG. 6 is a schematic sectional view showing an example of an apparatus for dispersing abrasive particles by an electrostatic spraying method.

FIG. 7 is a schematic diagram showing an example of an apparatus for coating abrasive particles with polymer in a gas phase.

FIG. 8 is schematic sectional view showing an abrasive particle to be contained in a slurry.

FIG. 9 is a characteristic diagram illustrating a pH dependency of a zeta potential.

FIG. 10 is a schematic front view showing a first embodiment of a polishing apparatus.

FIG. 11 is a schematic front view showing a second embodiment of the polishing apparatus.

### DETAILED DESCRIPTION

Embodiments of the present disclosure will now be described in detail with reference to the accompanying drawings.

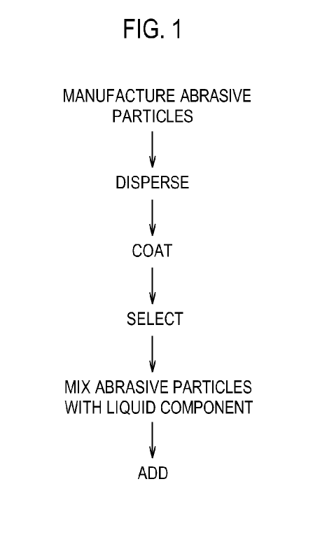

Descriptions will be first provided as to a method of manufacturing a slurry according to an exemplary embodiment, which is used in a process of manufacturing a mask blank by polishing a glass substrate by means of CMP. FIG. 1 is a conceptual diagram schematically showing example processes of the slurry-manufacturing method. Abrasive particles having a particle diameter of not more than 100 nm are manufactured from a raw material. The manufactured abrasive particles are dispersed. Each of the dispersed abrasive particles is coated with a polymer. The abrasive particles having a particle diameter of not more than 100 nm are selected from the coated abrasive particles. Thereafter, the selected abrasive particles are mixed with a liquid component of a slurry, thereby manufacturing a slurry. Further, a pH adjuster and a viscosity agent are added to the slurry.

Next, descriptions will be provided as to a process of manufacturing the abrasive particles. To mechanically polish a glass substrate, the abrasive particles must have a hardness higher than glass. Silica (silicon dioxide), carbon, etc. may be used as a material for the abrasive particles. In the process of manufacturing the abrasive particles, the abrasive particles may be synthesized from a raw material by a gas phase synthesis method, a liquid phase synthesis method, an aerosol heating method, a sol-gel method or a polymer-in-situ sol-gel method. The synthesized abrasive particles have a fine crystalline, multicrystalline or a three-dimensional structure made from silica or carbon. The three-dimensional structure may include a fullerene structure, a carbon nanotube structure or a basket-shaped three-dimensional structure made from silica.

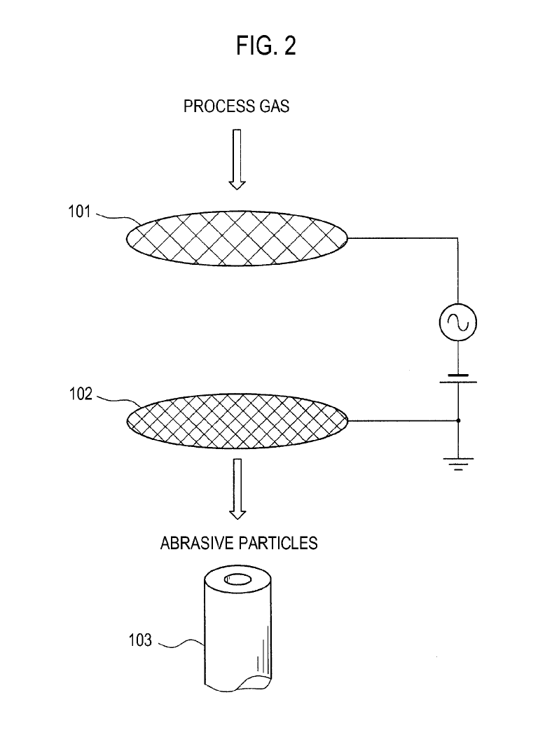

FIG. 2 is a schematic diagram showing an example apparatus for manufacturing the abrasive particles by the gas phase synthesis method. The abrasive particle manufacturing apparatus includes a cathode 101 and an anode 102, which have a mesh shape. A process gas flows from the cathode 101 toward the anode 102. The process gas is, for example, a gas obtained by diluting a TEOS (Tetraethyl orthosilicate) gas or a CF₄ gas with an argon gas. A RF (Radio Frequency) voltage is applied between the cathode 101 and the anode 102 while the process gas flows, thereby plasmarizing the process gas between the cathode 101 and the anode 102. Atoms in the plasmarized process gas are activated and chemically combined, thereby synthesizing the abrasive particles. Where the process gas includes the gas obtained by diluting a TEOS gas with an argon gas, the abrasive particles including silica as a main component may be synthesized. Where the process gas includes the gas obtained by diluting a CF₄ gas with an argon gas, the abrasive particles including carbon as a main component may be synthesized. The abrasive particle manufacturing apparatus includes a collector 103 for collecting the abrasive particles by suctioning. The synthesized abrasive particles pass through the anode 102 on the flow of the process gas and are then collected by the collector 103. Alternatively, the collector 103 may be configured to be positively electrified and to collect the abrasive particles by static electric force. The abrasive particles manufactured by the gas phase synthesis method are made up of fine particles including abrasive particles having a particle diameter of not more than 100 nm.

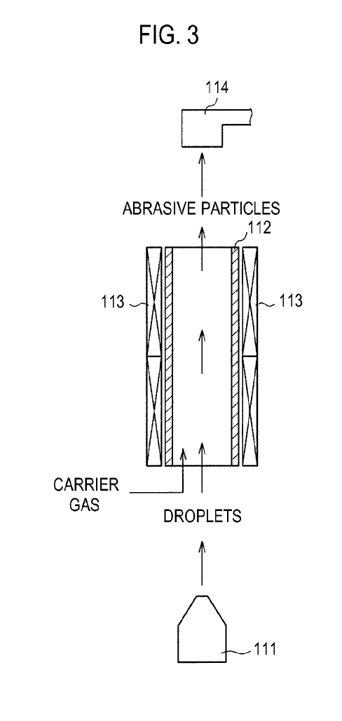

FIG. 3 is a schematic sectional view showing an example apparatus for manufacturing the abrasive particles by an aerosol heating method. The abrasive particle manufacturing apparatus includes a sprayer 111 for spraying a solution wherein a raw material for the abrasive particle dissolves in or is dispersed in a solvent. The sprayer 111 may include, for example, an ultrasonic sprayer. The sprayer 111 sprays the solution to produce droplets containing the raw material for the abrasive particle as well as the solvent. Further, the abrasive particle manufacturing apparatus includes a heating tube 112 with heaters 113 disposed therearound. A carrier gas including nitrogen or argon flows one way through an inner portion of the heating tube 112. Further, the heaters 113 heat the inside of the heating tube 112. Also, the temperature inside the heating tube 112 is controlled so as to become higher from an inlet of the carrier gas toward an outlet of the carrier gas. The droplets sprayed by the sprayer 111 flow into the heating tube 112 by the flow of the carrier gas and are heated while being carried inside the heating tube 12 by the carrier gas. As the droplets are heated, volatile components within the droplets evaporate, while nonvolatile components are bonded to one another to manufacture the abrasive particles. A collector 114 is disposed at the outlet of the heating tube 112. The collector 114 collects the abrasive particles discharged out of the heating tube 112 by the flow of the carrier gas. The manufactured abrasive particles are mad up of fine particles including abrasive particles having a particle diameter of not more than 100 nm. For example, when manufacturing the abrasive particles from the solution with silica dispersed therein using an aerosol heating method, the abrasive particles having a three-dimensional structure of silica can be manufactured, wherein silica within the droplets is bonded to one another by heating.

As for the sol-gel method, the solution with the raw material for abrasive particles dissolved in a solvent is made into a sol by a hydrolysis method and then the sol is made into a gel by a heating method and thereafter the gel is dried and pulverized, thereby manufacturing the abrasive particles of a fine particle size. For example, when using the TEOS as the raw material, the abrasive particles composed of silica can be manufactured.

Further, in another embodiment, abrasive particles may be manufactured, wherein a minor component causing a chemical reaction with glass is mixed with the main component such as silica or carbon for mechanically polishing glass. A substance chemically reacting with glass may include alumina, titania (titanium dioxide) or ceria (cerium oxide). These substances are for purposes of chemically polishing glass. It is possible to manufacture the abrasive particles wherein the minor component such as alumina, titania or ceria is mixed with the main component, by manufacturing a solution including the raw material for the main component such as silica as well as a raw material such as alumina, titania or ceria when manufacturing the abrasive particles by the sol-gel method. Further, it is possible to manufacture the abrasive particles including alumina as the main component.

Next, descriptions will be continued as to a process of dispersing the abrasive particles. The manufactured abrasive particles are fine particles and are prone to cohere. Accordingly, cohering abrasive particles are dispersed. The dispersing process may be performed in the following manner distribution using a membrane filter, dispersion using a bead mill, or dispersion using an electrostatic spraying method. According to the distribution using a membrane filter, the manufactured abrasive particles are filtered through a membrane filter such that both the cohering abrasive particles and the abrasive particles having a large particle diameter are removed therefrom. In this case, the abrasive particles having a particle diameter of more than 100 nm may be removed. When performing the distribution using the membrane filter, the abrasive particles having a particle diameter of not more than 100 nm can be obtained.

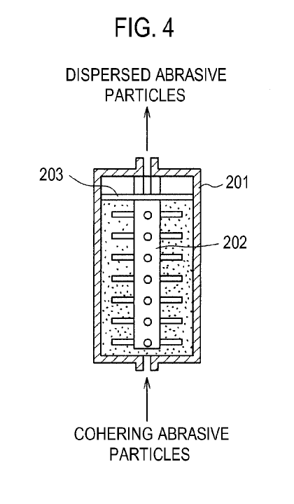

FIG. 4 is a schematic sectional view showing an example of a bead mill. The bead mill includes: a housing 201 having a shape of a cylinder with both bottoms; and rotor pins 202 provided in the housing 201. The rotor pins 202 are configured such that a large number of pins are joined to a rotating shaft centrally disposed in the cylinder. The housing 201 is filled with a large quantity of micrometer-sized beads, such as zirconia beads having a particle diameter of several micrometers (μm). As the rotor pins 202 rotate, the beads in the housing 201 are agitated. The cohering abrasive particles are inputted to the bead mill through an inlet. The inputted abrasive particles are brought into collision with the large quantity of beads being agitated and are grinded and crumbled up. Thus, the inputted abrasive particles become abrasive particles having a smaller particle diameter and are dispersed. A separator 203 for separating the beads and samples is provided in the vicinity of an outlet of the bead mill. The abrasive particles dispersed by the beads are separated from the beads by the separator 203 and then are discharged from the outlet.

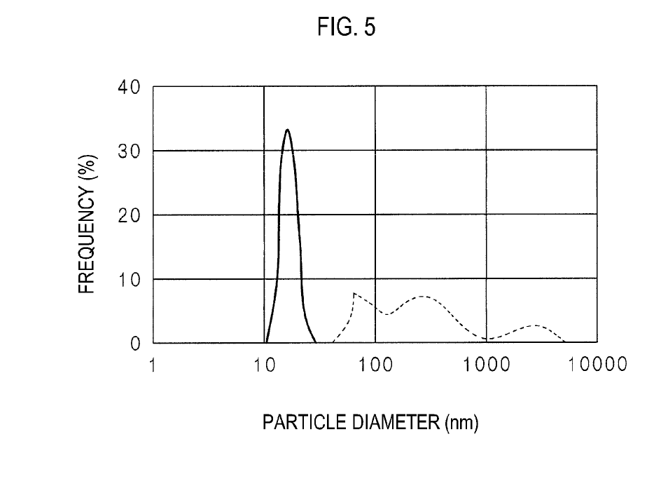

FIG. 5 is a characteristic diagram showing a particle diameter distribution of the abrasive particles before and after a process using a bead mill. A horizontal axis in FIG. 5 indicates the particle diameter of the abrasive particles on a logarithmic scale, while a vertical axis indicates a frequency, which the abrasive particle of each particle diameter accounts for in all abrasive particles. FIG. 5 shows the result from the process performed to abrasive particles comprised of silica by means of a bead mill using zirconia beads (particle diameter of several μm). A dashed line in FIG. 5 indicates the particle diameter distribution of the abrasive particles before the process. Before the process, the particle diameters are distributed over a wide range from about 100 nm to about 10000 nm. The abrasive particles before the process cohere with one another and a particle diameter relating thereto is shown as a particle diameter of an agglomerate of cohering abrasive particles. A solid line in FIG. 5 indicates the particle diameter distribution of the abrasive particles after the process using the bead mill for twenty minutes. It is apparent that the particle diameters of most abrasive particles are not more than 100 nm and the abrasive particles having a particle diameter of not more than 100 nm are dispersed. Further, it is possible to control the particle diameter distribution of the abrasive particles by controlling the size of the beads and a processing time in the bead mill.

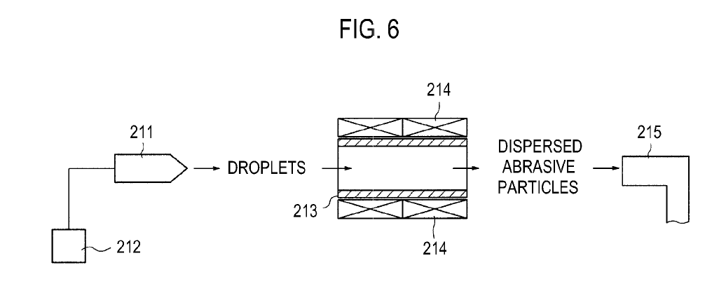

FIG. 6 is a schematic sectional view showing an example of an apparatus for dispersing abrasive particles by the electrostatic spraying method. The abrasive particle dispersing apparatus includes: an electrostatic sprayer 211 for electrostatically spraying a solution wherein abrasive particles are dispersed in a volatile solvent; and a pump 212 for injecting the solution into the electrostatic sprayer 211. The solution may be made by mixing cohering abrasive particles with the solvent and applying ultrasonic waves to disperse the abrasive particles. The electrostatic sprayer 211 applies a voltage of approximately 3 kV to the solution injected from the pump 212 to produce droplets having a size in the nanometer order. Further, the abrasive particle dispersing apparatus includes a heating tube 213 with heaters 214 disposed therearound. The droplets produced by the electrostatic sprayer 211 flow into the heating tube 213 on a carrier gas and are heated by the heaters 214 while being moved in the heating tube 213. As the droplets are heated, volatile components within the droplets evaporate, while nonvolatile components within the droplets remain as the dispersed abrasive particles. Since the droplets are sized in the nanometer order by the electrostatic spraying method, the particle diameters of the dispersed abrasive particles can be not more than 100 nm. A collector 215 is disposed at an outlet of the heating tube 213. The dispersed abrasive particles are discharged from the heating tube 213 and then collected by the collector 215. Further, the particle diameters of the abrasive particles can be adjusted by controlling a voltage value and a heating time in electrostatic spraying. To ensure that abrasive particles to be coated in a coating process described below finally have a particle diameter of not more than 100 nm, the abrasive particles having a particle diameter of less than 100 nm (e.g., abrasive particles having a particle diameter of not more than 70 nm) may be collected in the dispersing process.

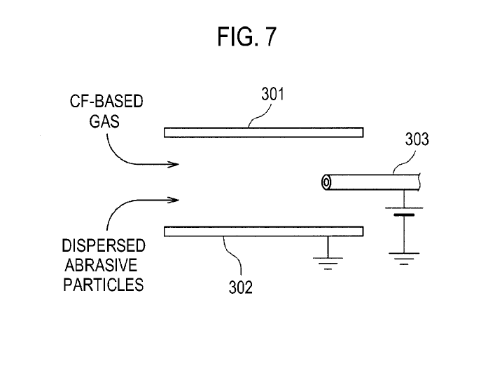

Next, a description will be provided as to a process of coating each of the dispersed abrasive particles. FIG. 7 is a schematic diagram showing an example of an apparatus for coating abrasive particles with a polymer in a gas phase. The abrasive particle coating apparatus includes an RF electrode 301 and a ground electrode 302. The abrasive particle coating apparatus applies an RF voltage to the RF electrode 301 and feeds a CF-based gas such as C₄F₈, C₅F₈, CH₂F₃ or CF₄ in between the RF electrode 301 and the ground electrode 302 to thereby plasmarize the CF-based gas between the electrodes. Further, the abrasive particle coating apparatus directs the flow of the dispersed abrasive particles into the plasma of the CF-based gas by a carrier gas. Then, the dispersed abrasive particles are negatively electrified due to collisions with electrons in the plasma and thus are trapped between the RF electrode 301 and the ground electrode 302. The CF-based gas causes polymerization reaction on surfaces of the trapped abrasive particles to thereby make a CF-based polymer such as polytetrafluoroethylene. Then, the abrasive particles are coated with the CF-based polymer. After performing the process in the plasma for a predetermined time, the abrasive particle coating apparatus collects the abrasive particles coated with the polymer by means of a collector 303 that is electrified with positive electric potential. Through the coating process, the abrasive particles manufactured untill the dispersing process become nucleuses and such nucleuses are coated with a polymer.

The positive electric potential of the collector 303 may be preferably in some embodiments in a range of +40V to +100V. Since the abrasive particles within the plasma are negatively electrified, the collector 303 electrified with positive electric potential can collect such abrasive particles. Where the positive electric potential is not less than +40V, a force of the collector 303 that attracts the abrasive particles becomes stronger due to a great potential difference. This improves collection efficiency for the abrasive particles. Further, where the positive electric potential is not more than +100V, positive ions within the plasma are repulsed from the collector 303 electrified with positive electric potential, thereby weakening ion viscosity hindering the abrasive particles from approaching the collector 303. This also improves the collection efficiency for the abrasive particles.

Directing the dispersed abrasive particles to flow in and collecting the abrasive particles coated with a polymer may be performed in sequence. The abrasive particles that are coated with a certain amount of a polymer increase particle diameter and mass and thus stay down within the plasma. Thus, when the collector 303 collects the abrasive particles staying down, the polymer-coated abrasive particles can be collected in sequence. Alternatively, the collector 303 may be configured to collect the abrasive particles by suctioning instead of being electrified with positive electric potential. Further, the particle diameters of the polymer-coated abrasive particles can be adjusted by controlling the time that it takes from the time of directing the flow of the abrasive particles in between the RF electrode 301 and the ground electrode 302, to the time of collecting the abrasive particles by the collector 303.

In the coating process, the abrasive particles may be coated with a polymer other than the CF-based polymer, such as PMMA (Polymethylmethacrylate) resin. Any one of those polymers is softer than the nucleus of the abrasive particle including silica or carbon as a main component. Further, the coating process is not limited to coating in the gas phase. The abrasive particles may be coated with a polymer by polymerization on the surface of the abrasive particle in a liquid phase.

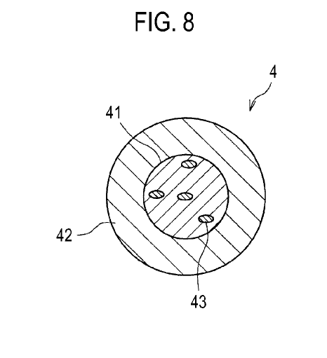

FIG. 8 is a schematic sectional view showing the abrasive particle to be contained in a slurry. The abrasive particle 4 is structured such that a nucleus 41 including a substance for mechanically polishing glass such as silica or carbon as a main component is coated with a soft 42 such as a CF-based polymer. Further, a minor component 43 such as alumina, titania or ceria is mingled in the nucleus 41. Voids may exist inside the abrasive particle 4. In another embodiment, the slurry may be manufactured by using abrasive particles that does not contain the minor component 43. In yet another embodiment, the slurry may be manufactured by using abrasive particles without a coating of the polymer.

Next, descriptions will be continued as to a process of selecting abrasive particles. In the selecting process, the abrasive particles are filtered by a membrane filter. As a result, abrasive particles having a particle diameter of more than 100 nm are removed, while abrasive particles having a particle diameter of not more than 100 nm are collected. The coating process and the selecting process may be combined together by selectively collecting the polymer-coated abrasive particles (the particle diameter including the polymer coating is particularly sized as not more than 100 nm) in the coating process. Further, in another embodiment using the abrasive particles without a coating of the polymer, the dispersing process and the selecting process may be combined together by omitting the coating process and instead filtering abrasive particles by the membrane filter in the dispersing process. Further, in yet another embodiment using the abrasive particles without a coating of the polymer, the dispersing process and the selecting process may be combined together by omitting the coating process and instead selectively collecting abrasive particles having a particle diameter of not more than 100 nm in the dispersing process using the bead mill or the electrostatic spraying method.

Next, a process of mixing abrasive particles with a liquid component will be described. In the mixing process, to manufacture a slurry, the selected abrasive particles are mixed with the liquid component of the slurry as they are dispersed. The abrasive particles are mixed with water by, for example, putting the abrasive particles into the water while agitating the water. Through the above-described processes a slurry is manufactured, which does not contain the abrasive particles having a particle diameter of more than 100 nm, and wherein the abrasive particles having a particle diameter of not more than 100 nm are dispersed in the liquid component.

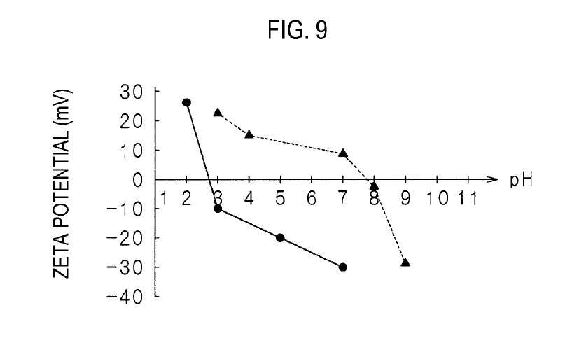

Next, an adding process will be described. When a slurry for use in polishing glass is alkaline, a hydration reaction of the glass proceeds to thus promote the polishing. Accordingly, making a pH of the slurry not less than at least seven (7) allows for more efficient polishing for the glass. Further, a zeta potential between the abrasive particles and the liquid component within the slurry depends upon the pH of the slurry. The greater an absolute value of the zeta potential, the stronger a repulsion force between the abrasive particles becomes. This can prevent the abrasive particles from cohering in the slurry. FIG. 9 is a characteristic diagram illustrating a pH dependency of a zeta potential. A horizontal axis in FIG. 9 indicates the pH of the slurry, while a vertical axis indicates the zeta potential. In FIG. 9, a solid line indicates the pH dependency of the zeta potential when the abrasive particles are composed of silica, whereas a dashed line indicates the pH of the zeta potential when the abrasive particles are composed of alumina Referring to FIG. 9, when the component of the abrasive particles is silica, the absolute value of the zeta potential becomes not less than 30 mV when the pH is 7 or more. Further, when the component of the abrasive particles is alumina, the pH must be at least 8.5 or more so that the absolute value of the zeta potential can be 20 mV or more. Accordingly, as to the slurry wherein the main component of the abrasive particles is silica, the pH is preferably set not less than 7. And, as to the slurry wherein the main component of the abrasive particles is alumina, the pH is preferably set not less than 8.5. A too high pH can make machines using the slurry rapidly corrode. Thus, the pH is preferably set in some embodiments to not more than 11. In the adding process, to adjust the pH of the slurry in a range of not less than 7 and not more than 11 or not less than 8.5 and not more than 11, a pH adjuster such as NaOH, KOH or NH₄OH is added to the slurry.

Further, to adjust the viscosity of the slurry, a viscosity agent is added to the slurry in the adding process. The high viscosity of the slurry decreases a rate of the abrasive particles flowing out of the slurry during polishing, thereby providing efficient polishing for the glass substrate. The viscosity agent to be added to the slurry may include mono ethylene glycol, propylene glycol, ethylene glycol or diethylene glycol. Either the pH adjuster or the viscosity agent may be added to the slurry. Further, the adding process may be omitted.

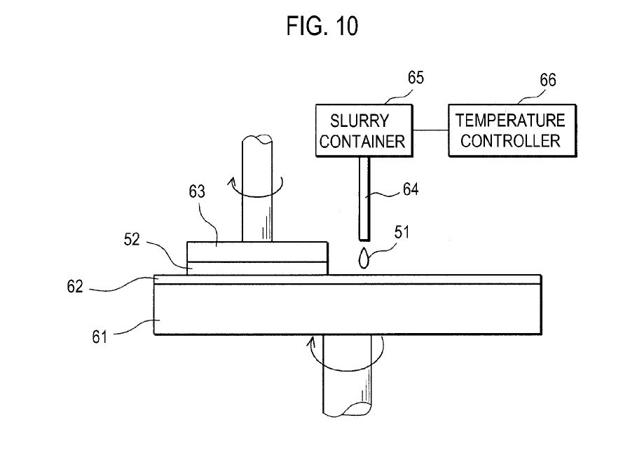

In one embodiment, a mask blank is manufactured by using the slurry manufactured by the above-described slurry manufacturing method and polishing a glass substrate by CMP. Subsequently, a polishing method will be described below. FIG. 10 is a schematic front view showing a first embodiment of a polishing apparatus. The polishing apparatus includes a flat turn table 61. A polishing pad 62 formed of a resin material is laid on the turn table 61. Further, the polishing apparatus includes a holder 63 for holding the glass substrate 52 opposite the polishing pad 62. The holder 63 functions to rotate the glass substrate 52 while pressing the glass substrate 52. Further, the polishing apparatus includes a slurry container 65 and a nozzle 64 connected to the slurry container 65. A slurry 51 within the slurry container 65 is fed to the polishing pad 62 through the nozzle 64. Further, the polishing apparatus includes a temperature controller 66 for controlling the temperature of the slurry 51 in the slurry container 65. The temperature controller 66 measures a temperature around the slurry 51 within the slurry container 65, a temperature around the slurry fed to the polishing pad 62, and a temperature of the slurry 51 within the slurry container 65 by means of a temperature sensor (not shown). Further, the temperature controller 66 controls the temperature of the slurry 51 within the slurry container 65 by means of a heater (not shown) such that the temperature of the slurry 51 within the slurry container 65 becomes higher than the temperature around the slurry 51.

The polishing apparatus brings the glass substrate 52 held by the holder 63 into abutment with the polishing pad 62 and rotates the turn table 61 and the holder 63 while feeding the slurry 51 onto the polishing pad 62, thereby performing the CMP on the glass substrate 52. As the turn table 61 and the holder 63 are rotated, the polishing pad 62 and the glass substrate 52 are separately rotated and the slurry 51 fed onto the polishing pad 62 infiltrates in between the polishing pad 62 and the glass substrate 52. Then, the polishing pad 62 and the glass substrate 52 are rubbed against each other with the slurry 51 therebetween and thus the glass substrate 52 is chemically mechanically polished.

The abrasive particles having a particle diameter of not more than 100 nm are contained and dispersed in the slurry 51. Thus, either the abrasive particles having a particle diameter of more than 100 nm or the agglomerate of the cohering abrasive particles does not contact the glass substrate 52 and thus does not cause big scratches on the glass substrate 52. Accordingly, it is possible in some embodiments to suppress the generation of scratches of 70 nm or more on the glass substrate 52. The absolute value of the zeta potential in the slurry 51 is high due to the addition of the pH adjuster to the slurry 51. Thus, the abrasive particles have difficultly in cohering within the slurry 51. This more certainly prevents the agglomerate of the cohering abrasive particles from causing scratches of 70 nm or more on the glass substrate 52. Furthermore, the abrasive particles are coated with the soft polymer. Thus, when the abrasive particles are pressed against the glass substrate 52, such pressing force does not concentrate on one point, but rather distributes and thus it is difficult to cause scratches.

Since the abrasive particles of the slurry 51 includes a substance having a hardness harder than glass such as silica or carbon as a main component, the glass substrate 52 is mechanically polished by the abrasive particles. Further, the abrasive particles include a substance that chemically reacts with glass such as alumina, titania or ceria as a minor component. Thus, the minor component chemically reacts with the surface of the glass substrate 52 and the glass substrate 52 is chemically polished thereby. Accordingly, the efficient polishing for the glass substrate 52 is performed. Further, adding the pH adjuster to the slurry 51 makes the slurry 51 alkaline. This allows for efficient polishing of the glass substrate 52. Moreover, adding the viscosity agent to the slurry 51 reduces the ratio of abrasive particles flowing out of the slurry 51 during polishing. This also allows for more efficient polishing for the glass substrate 52.

The temperature controller 66 controls the temperature of the slurry 51 so as to be higher than the ambient condition, thereby preventing foreign particles in the atmosphere from mixing into the slurry 51 by a thermophoretic effect. Since the foreign particles are not permitted to mix into the slurry, it is possible to prevent scratches from occurring due to contact of foreign particles with the glass substrate 52. To reliably prevent the mixing of the foreign particles, the temperature controller 66 preferably in some embodiments controls the temperature of the slurry 51 so as to be higher by 5° C. or more than the ambient condition. As such, the temperature controller 66 controls the temperature of the slurry 51, thereby suppressing the generation of the scratches of 70 nm or more on the glass substrate 52.

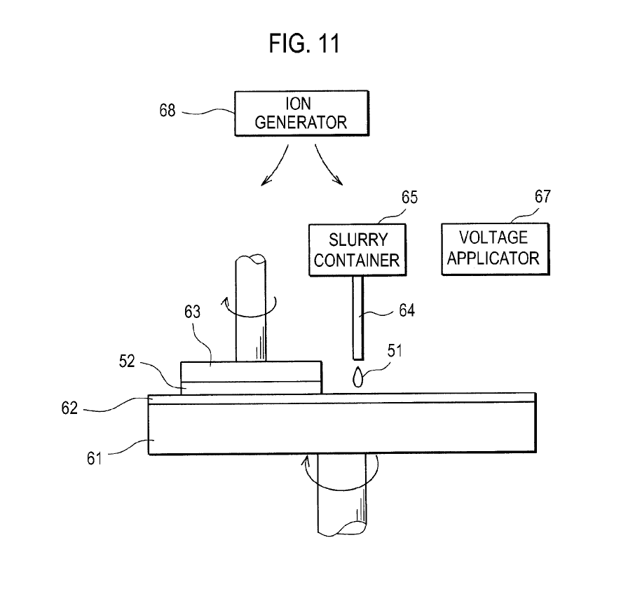

FIG. 11 is a schematic front view showing a second embodiment of the polishing apparatus. The polishing apparatus according to the second embodiment includes a voltage applicator 67 for applying a voltage to the slurry 51 within the slurry container 65, and an ion generator 68 for generating atmospheric ions, instead of the temperature controller 66. The configuration of the polishing apparatus according to this embodiment is the same as that of the first embodiment shown in FIG. 10 except for the aforementioned difference. Thus, like reference numerals are denoted to the like parts and descriptions thereon will be omitted. Similar to the first embodiment, the polishing apparatus according to the second embodiment performs CMP on the glass substrate 52 and thus can efficiently polish the glass substrate 52 while suppressing the generation of scratches.

The voltage applicator 67 applies a constant voltage of +100V or −100V to the slurry 51 within the slurry container 65. The ion generator 68 is configured to generate atmospheric ions having the same polarity as the voltage applied by the voltage applicator 67 and emit the generated atmospheric ions to the polishing apparatus. The ion generator 68 may include an atmospheric ion generating device configured to irradiate an ultraviolet ray or a soft X ray to a carrier gas such as nitrogen or argon to generate atmospheric ions. Further, the atmospheric ion generating device may be configured to perform a corona discharge in a carrier gas. The ion generator 68 emits the carrier gas and then emits the atmospheric ions into the polishing apparatus on the flow of the carrier gas. Alternatively, the ion generator 68 may be configured to generate bipolar ions and to selectively emit atmospheric ions having the same polarity as the voltage applied by the voltage applicator 67. Further alternatively, the ion generator 68 may be configured to generate atmospheric ions from aerosol.

The atmospheric ions having the same polarity as the voltage applied to the slurry 51 are supplied to the polishing apparatus. Thus, in the polishing apparatus, the atmospheric ions are repulsed from the slurry 51 and thus an air flow is generated in a direction away from the slurry 51. Such an air flow prevents foreign particles in the atmosphere from mixing into the slurry 51. As such, supplying the atmospheric ions to the polishing apparatus can suppress the generation of the scratches of 70 nm or more on the glass substrate 52, which the foreign particles mixed into the slurry 51 may cause. Alternatively, the ion generator 68 may generate the atmospheric ions by using an ultraviolet ray. In such a case, the ultraviolet ray prevents bacteria from occurring within the slurry 51. Since the occurrence of bacteria is prevented, the CMP on the glass substrate 51 can be performed with better efficiency while preventing degeneration of the slurry 51 such as a change in a pH and further suppressing the generation of the scratches on the glass substrate 52.

As described above in detail, according to the embodiments disclosed herein, the CMP on the glass substrate 51 is performed with better efficiency while suppressing the generation of the scratches on the glass substrate 52. Accordingly, scratchless high-quality mask blanks can be efficiently manufactured. Further, defectless high-quality photo masks for EUV exposure can be manufactured by using such mask blanks. The slurry according to the present disclosure should not be limited to the manufacture of mask blanks. The slurry may be used for generally polishing glass. For example, the slurry according to the present disclosure may be used for polishing a glass-made lens in order to manufacture lenses with fewer scratches.

What is claimed is:

1. A method of manufacturing a slurry containing abrasive particles for polishing a glass and a liquid component, the method comprising:
manufacturing abrasive particles having a particle diameter of not more than 100 nm;
dispersing the manufactured abrasive particles; and
mixing the abrasive particles with the liquid component as the abrasive particles are dispersed.

2. The method of claim 1, further comprising coating the dispersed abrasive particles with a polymer softer than the abrasive particle.

3. The method of claim 1, wherein the abrasive particle includes: a substance for mechanically polishing the glass as a main component; and a substance for chemically reacting with the glass as a minor component.

4. The method of claim 1, further comprising selecting the abrasive particle having a particle diameter of not more than 100 nm prior to said mixing the abrasive particles with the liquid component.

5. The method of claim 1, further comprising adding a pH adjuster to maintain a pH over 7 or more.

6. The method of claim 1, further comprising adding a viscosity agent.

7. A slurry comprising:
abrasive particles for polishing a glass; and
a liquid component,
wherein the slurry does not contain the abrasive particles having a particle diameter of more than 100 nm and the abrasive particles having a particle diameter of not more than 100 nm are dispersed in the liquid component.

8. The slurry of claim 7, wherein the abrasive particle includes a nucleus and a polymer softer than the nucleus, the nucleus being coated with the polymer.

9. The slurry of claim 7, wherein the abrasive particle includes: a substance for mechanically polishing the glass as a main component; and a substance for chemically reacting with the glass as a minor component.

10. The slurry of claim 7, wherein a pH of the slurry is 7 or more.

11. The slurry of claim 7, further comprising a viscosity agent.

12. A method of chemical mechanical polishing a glass using the slurry according to claim 7.

13. The method of claim 12, including controlling a temperature of the slurry so as to be higher than an atmospheric temperature around the slurry.

14. The method of claim 12, including:
applying a voltage to the slurry; and
supplying ions around the slurry, the ions having the same polarity as the voltage.

15. A polishing apparatus comprising:
a device for feeding the slurry according to claim 7;
a device for polishing a glass by using the fed slurry; and
a device for controlling a temperature of the slurry so as to be higher than an atmospheric temperature around the slurry.

16. A polishing apparatus comprising:
a device for feeding the slurry according to claim 7;
a device for polishing a glass by using the fed slurry;
a device for applying a voltage to the slurry; and
a device for supplying ions around the slurry, the ions having the same polarity as the voltage.
